(19) United States
(12) Patent Application Publication
(10) Pub. No.: US 2025/0279404 A1
(43) Pub. Date: Sep. 4, 2025

(54) SEMICONDUCTOR PACKAGE

(71) Applicant: Samsung Electronics Co., Ltd., Suwon-si (KR)

(72) Inventor: Chulho JUNG, Suwon-si (KR)

(73) Assignee: Samsung Electronics Co., Ltd., Suwon-si (KR)

(21) Appl. No.: 19/060,071

(22) Filed: Feb. 21, 2025

(30) Foreign Application Priority Data
Feb. 29, 2024 (KR) 10-2024-0029764

(51) Int. Cl. H01L 25/18; H01L 23/00; H01L 23/29; H01L 23/498; H01L 23/538; H10B 80/00; H10D 80/30

(52) U.S. Cl. CPC H01L 25/18; H01L 23/295; H01L 23/49816; H01L 23/49822; H01L 23/49833; H01L 23/5385; H01L 24/16; H01L 2224/16227; H01L 2924/1431; H10B 80/00; H10D 80/30

(57) ABSTRACT

A semiconductor package includes a first redistribution layer (RDL) including a first redistribution wiring structure, a first semiconductor chip on the first RDL and electrically connected to the first redistribution wiring structure, a molding layer on the first RDL and covering the first semiconductor chip and having one or more surfaces at least partially defining a recess at an upper surface of the molding layer, a planarization layer contacting the upper surface of the molding layer and having a flat upper surface, and a second redistribution layer (RDL) on the planarization layer and including a second redistribution wiring structure. The upper surface of the molding layer and a lower surface of the planarization layer collectively at least partially define a void between the upper surface of the molding layer and the lower surface of the planarization layer.

### CROSS-REFERENCE TO RELATED APPLICATION

This application claims priority under 35 U.S.C. § 119 to Korean Patent Application No. 10-2024-0029764, filed on Feb. 29, 2024 in the Korean Intellectual Property Office (KIPO), the contents of which are herein incorporated by reference in their entirety.

### BACKGROUND

### 1. Field

Example embodiments relate to semiconductor packages.

### 2. Description of the Related Art

In some methods of manufacturing a semiconductor package, a first semiconductor chip is mounted on a first redistribution layer (RDL), a molding layer is formed on the first RDL to cover the first semiconductor chip, a second RDL is formed on the molding layer, and a second semiconductor chip is mounted on the second RDL.

### SUMMARY

Some example embodiments provide a semiconductor package having enhanced electrical characteristics and/or structural stability. Such a semiconductor package may have enhanced electrical characteristics and/or structural stability based on having a molding layer with a relatively high hardness and/or a relatively small coefficient of thermal expansion (CTE) while also having reduced, minimized, or prevented likelihood of electrical shorts.

According to some example embodiments, a semiconductor package may include a first redistribution layer (RDL), a first semiconductor chip, a molding layer, a planarization layer, and a second redistribution layer (RDL). The first RDL may include a first redistribution wiring structure. The first semiconductor chip may be on the first RDL and may be electrically connected to the first redistribution wiring structure. The molding layer may be on the first RDL. The molding layer may cover the first semiconductor chip. The molding layer may have one or more surfaces at least partially defining a recess at an upper surface of the molding layer. The planarization layer may contact the upper surface of the molding layer. The planarization layer may have a flat upper surface. The second redistribution layer (RDL) may be on the planarization layer and may include a second redistribution wiring structure. The upper surface of the molding layer and a lower surface of the planarization layer may collectively at least partially define a void between the upper surface of the molding layer and the lower surface of the planarization layer.

According to some example embodiments, a semiconductor package may include a first redistribution layer (RDL), a first semiconductor chip, a molding layer, a planarization layer, and a second redistribution layer (RDL). The first RDL may include a first redistribution wiring structure. The first semiconductor chip may be on the first RDL and may be electrically connected to the first redistribution wiring structure. The molding layer may be on the first RDL and may cover the first semiconductor chip. The molding layer may include a molding member and a filler in the molding member, the filler having a shell shape having one or more inner surfaces at least partially defining a recess into an interior of the molding layer in the vertical direction from an uppermost surface of the molding member. The planarization layer may contact an upper surface of the molding layer. The planarization layer may have a flat upper surface and may include a pressure sensitive adhesive (PSA). The second redistribution layer (RDL) may be on the planarization layer and may include a second redistribution wiring structure.

According to some example embodiments, a semiconductor package may include a first redistribution layer (RDL), a first conductive connection member, a second conductive connection member, a first semiconductor chip, a molding layer, a planarization layer, a second redistribution layer (RDL), a conductive post structure, a third conductive connection member, and a second semiconductor chip. The first RDL may include a first redistribution wiring structure. The first conductive connection member may be on a lower surface of the first RDL and may contact the first redistribution wiring structure. The second conductive connection member may be on the first RDL and may contact the first redistribution wiring structure. The first semiconductor chip may contact an upper surface of the second conductive connection member. The molding layer may be on the first RDL. The molding layer may cover the first semiconductor chip and the second conductive connection member. The molding layer may have one or more surfaces at least partially defining a recess at an upper surface of the molding layer. The planarization layer may contact the upper surface of the molding layer. The planarization layer may have a flat upper surface, a second redistribution layer (RDL) contacting an upper surface of the planarization layer and including a second redistribution wiring structure. The conductive post structure may extend through both of the molding layer and the planarization layer and may contact both of the first redistribution wiring structure and the second redistribution wiring structure. The third conductive connection member may be on the second RDL and may contact the second redistribution wiring structure. The second semiconductor chip may contact an upper surface of the third conductive connection member. The upper surface of the molding layer and a lower surface of the planarization layer may collectively at least partially define a void between the upper surface of the molding layer and the lower surface of the planarization layer.

In a method of manufacturing the semiconductor package in accordance with some example embodiments, even though the recess is formed at the upper surface of the molding layer covering a lower semiconductor chip, after forming the planarization layer having the flat upper surface on the molding layer, a redistribution layer may be formed on (e.g., directly on or indirectly on) the flat upper surface of the planarization layer, so that a likelihood of an electrical short between the elements of the redistribution wiring structure in the redistribution layer may be reduced, minimized, or prevented. Accordingly, the semiconductor package may have enhanced electrical characteristics and/or improved reliability based on the reduced, minimized, or prevented likelihood of an electrical short in the redistribution layer formed on the planarization layer (e.g., directly or indirectly on the flat upper surface of the planarization layer) while still providing a molding layer with a relatively high hardness and/or a relatively small coefficient of thermal expansion (CTE) (e.g., based on the molding layer including a filler in a molding member).

### BRIEF DESCRIPTION OF THE DRAWINGS

FIG. 1 is a cross-sectional view illustrating a semiconductor package in accordance with some example embodiments.

FIGS. 2, 3, 4, 5, 6, 7, and 8 are cross-sectional views illustrating a method of manufacturing a semiconductor package in accordance with some example embodiments.

FIGS. 9, 10, and 11 are cross-sectional views illustrating a method of forming a second conductive post in a planarization layer of a semiconductor package in accordance with some example embodiments.

FIGS. 12 and 13 are cross-sectional views illustrating semiconductor packages in accordance with some example embodiments.

FIG. 14 is a drawing illustrating an electrical short generated in a second redistribution wiring structure of a semiconductor package in accordance with a comparative embodiment.

### DETAILED DESCRIPTION

Hereinafter, example embodiments will be explained in detail with reference to the accompanying drawings. A direction parallel or substantially parallel to an upper surface of a substrate, chip or redistribution layer may be referred to as a horizontal direction, and a direction perpendicular or substantially perpendicular to the upper surface of the substrate, chip or redistribution layer may be referred to as a vertical direction.

To clearly describe the present inventive concepts, parts that are irrelevant to the description in the drawings are omitted, and like numerals refer to like or similar constituent elements throughout the specification. Further, since sizes and thicknesses of constituent members shown in the accompanying drawings are arbitrarily given for better understanding and ease of description, the present inventive concepts are not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

Throughout this specification and the claims that follow, when it is described that an element is “coupled/connected” to another element, the element may be “directly coupled/connected” to the other element or “indirectly coupled/connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, plate, etc. is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion and does not necessarily mean positioned on the upper side of the object portion based on a gravitational direction.

Further, throughout the specification, the phrase “in a plan view” means when an object portion is viewed from above, and the phrase “in a cross-sectional view” means when a cross-section taken by vertically cutting an object portion is viewed from the side.

It will be understood that elements and/or properties thereof (e.g., structures, surfaces, directions, or the like), which may be referred to as being “perpendicular,” “parallel,” or the like with regard to other elements and/or properties thereof (e.g., structures, surfaces, directions, or the like) may be “perpendicular,” “parallel,” or the like or may be “substantially perpendicular” or “substantially parallel,” respectively, with regard to the other elements and/or properties thereof.

Elements and/or properties thereof (e.g., structures, surfaces, directions, or the like) that are “substantially perpendicular” or “substantially parallel” with regard to other elements and/or properties thereof will be understood to be “perpendicular” or “parallel,” respectively, with regard to the other elements and/or properties thereof within manufacturing tolerances and/or material tolerances and/or have a deviation in magnitude and/or angle from “perpendicular” or “parallel,” respectively, with regard to the other elements and/or properties thereof that is equal to or less than 10% (e.g., a. tolerance of ±10%).

It will be understood that surfaces which may be referred to as being “flat” may be understood to be “planar” or “substantially planar.” It will be understood that surfaces which may be referred to as being “planar” may be “planar” or may be “substantially planar.” Surfaces that are “substantially planar” will be understood to be “planar” within manufacturing tolerances and/or material tolerances and/or have surface portions with a deviation in magnitude and/or angle from “planar,” respectively, with regard to the other portions of the surfaces that is equal to or less than 10% (e.g., a. tolerance of ±10%).

It will be understood that elements and/or properties thereof may be recited herein as being “identical”, “the same”, or “equal” as other elements and/or properties thereof, and it will be further understood that elements and/or properties thereof recited herein as being “identical” to, “the same” as, or “equal” to other elements and/or properties thereof may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to, equal to or substantially equal to, and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element or property is referred to as being identical to, equal to, or the same as another element or property, it should be understood that the element or property is the same as another element or property within a desired manufacturing or operational tolerance range (e.g., ±10%).

It will be understood that elements and/or properties thereof described herein as being “substantially” the same, equal, and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

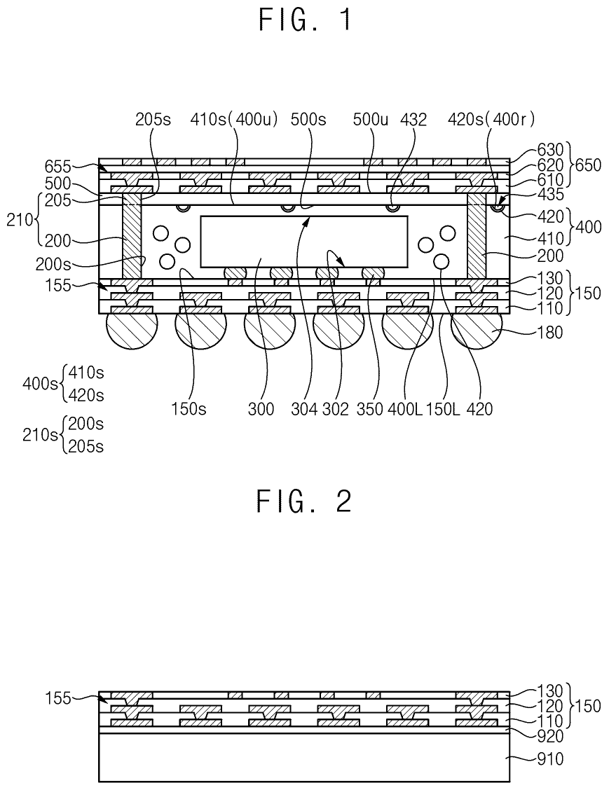

FIG. 1 is a cross-sectional view illustrating a semiconductor package in accordance with some example embodiments.

Referring to FIG. 1, the semiconductor package may include a first semiconductor chip 300, a conductive post structure 210, a first molding layer 400 (also referred to herein interchangeably as a molding layer), a planarization layer 500 and a second redistribution layer (RDL) 650 on a first redistribution layer (RDL) 150.

The semiconductor package may further include first and second conductive connection members 180 and 350.

The first RDL 150 may include insulation layers stacked in the vertical direction (which may be perpendicular or substantially perpendicular to an upper surface 150s of the first RDL 150) and a first redistribution wiring structure 155 in the insulation layers, and the first redistribution wiring structure 155 may include, e.g., redistribution wirings, vias, contact plugs, conductive pads, etc.

FIG. 1 shows that the first RDL 150 includes first, second, and third insulation layers 110, 120, and 130 sequentially stacked in the vertical direction, and the first redistribution wiring structure 155 is formed in the first, second and third insulation layers 110, 120, and 130. However, the inventive concepts are not limited thereto, and the first RDL 150 may include less than or more than three insulation layers sequentially stacked in the vertical direction. In some example embodiments, the first RDL 150 may omit one or more of the first, second, or third insulation layers 110, 120, or 130.

Each of the redistribution wirings, vias, contact plugs, conductive pads, etc., included in the first redistribution wiring structure 155 may have various types of layouts in the insulation layers.

Each of the first to third insulation layers 110, 120 and 130 may include an organic material, e.g., photo imageable dielectric (PID). The organic material may include, e.g., polyimide, polybenzoxazole, etc. The redistribution wirings, vias, contact plugs, conductive pads, etc., included in the first redistribution wiring structure 155 may include a conductive material, e.g., a metal, a metal nitride, a metal silicide, etc.

The first conductive connection member 180 may be disposed on a lower surface of the first RDL 150, and may contact a portion of the first redistribution wiring structure 155, e.g., a conductive pad. In some example embodiments, a plurality of first conductive connection members 180 may be spaced apart from each other in the horizontal direction (which may be parallel or substantially parallel to the upper surface 150s of the first RDL 150), and may be mounted on and electrically connected to a package substrate, e.g., a printed circuit board (PCB), a mother board, etc.

The first conductive connection member 180 may be, e.g., a conductive bump or a conductive ball. The first conductive connection member 180 may include solder that is an alloy or a metal. For example, the first conductive connection member 180 may include an alloy of tin, silver, aluminum, nickel, copper, etc., or a metal such as tin, silver, aluminum, nickel, copper, etc. For example, the first conductive connection member 180 may include tin, silver, aluminum, nickel, copper, or any combination thereof.

The first semiconductor chip 300 may be mounted on the first RDL 150 with the second conductive connection member 350 therebetween (e.g., directly or indirectly therebetween), and thus may be electrically connected to the first redistribution wiring structure 155. The first semiconductor chip 300 may include first and second surfaces 302 and 304 opposite to each other in the vertical direction. The first surface 302 of the first semiconductor chip 300 may face downwardly in the vertical direction, and may contact an upper surface of the second conductive connection member 350.

The first semiconductor chip 300 may include a volatile memory device such as a DRAM device, an SRAM device, etc., or a non-volatile memory device such as a flash memory device, an EEPROM device, etc. In some example embodiments, the first semiconductor chip 300 may include a logic device such as a controller.

The first molding layer 400 may be disposed on (e.g., directly on or indirectly on) the first RDL 150, and may cover both of the first semiconductor chip 300 and the second conductive connection member 350. The first molding layer 400 may directly contact the first RDL 150. The first molding layer 400 may directly contact the second conductive connection member 350. The first molding layer 400 may directly contact the first semiconductor chip 300. The first molding layer 400 may directly contact the first conductive post 200. The first molding layer 400 may include, e.g., epoxy molding compound (EMC), and the EMC may have a molding member 410 including, e.g., epoxy and a filler 420 in the molding member 410.

The filler 420 may include a spherical filler such as silica (SiO₂), alumina (Al₂O₃), boron nitride (BN), aluminum nitride (AlN), and/or diamond. The filler 420 may have a hardness higher than that of the molding member 410, and the filler 420 may have a coefficient of thermal expansion (CTE) lower than that of the molding member 410.

The filler 420 may be disposed at an inside of the molding member 410 (e.g., partially or entirely surrounded by the molding member 410 in both of the horizontal direction and the vertical direction) and have a spherical shape surrounded (e.g., partially or entirely surrounded in both of the horizontal direction and the vertical direction) by the molding member 410. The filler 420 may also be disposed at an upper portion of the molding member 410 and have a shell shape surrounding a recess 435 on or at an upper surface of the molding member 410. For example, the filler 420 may have one or more inner surfaces 420s at least partially defining a recess 435 into the first molding layer 400 (e.g., into an interior of the first molding layer 400, towards a lower surface 400L of the first molding layer 400, etc.) in the vertical direction from a planar or substantially planar uppermost surface portion 400u of the first molding layer 400, which may be defined by the uppermost surface 410s of the molding member 410, where the uppermost surface 410s may be planar or substantially planar and extending in the horizontal direction. As a result, the uppermost surface 410s and the one or more inner surfaces 420s may at least partially define an upper surface 400s of the first molding layer 400 that has one or more recesses 435 at the upper surface 400s, such that the upper surface 400s of the first molding layer 400 is not flat (e.g., is not planar or substantially planar). For example, the first molding layer 400 may have one or more surfaces (e.g., one or more exposed inner surfaces 420s) that at least partially define a recess 435 at the upper surface 400s of the first molding layer 400, including for example a recess 435 into the first molding layer 400 (e.g., into an interior of the first molding layer 400, towards a lower surface 400L of the first molding layer 400, etc.) in the vertical direction from an uppermost surface portion 400u of the first molding layer 400, where the uppermost surface portion 400u (at least partially defined by uppermost surface 410s) may be planar or substantially planar and extending in the horizontal direction (e.g., a direction extending parallel or substantially parallel to the upper surface 150s of the first RDL 150). As shown, the uppermost surface 410s of the molding member 410 may define an uppermost surface portion 400u of the upper surface 400s of the first molding layer 400, where the uppermost surface portion 400u is planar or substantially planar and extending in the horizontal direction, and the one or more inner surfaces 420s may define one or more respective recessed surface portions 400r of the upper surface 400s that are recessed from the uppermost surface portion 400u towards the lower surface 400L of the first molding layer 400 in the vertical direction.

In some example embodiments, the planarization layer 500 may include an element of a lamination tape, e.g., pressure sensitive adhesive (PSA). The PSA may include, e.g., acryl, imide, silicon, etc.

In some example embodiments, no recess may be formed on an upper surface of the planarization layer 500, which may be different from the first molding layer 400 having the recess 435 thereon, and thus the planarization layer 500 may have a flat upper surface 500u. It will be understood that a “flat” surface as described herein refers to an upper surface that is planar or substantially planar, and therefore the flat upper surface 500u will be understood to be an upper surface 500u that is planar or substantially planar and extending in the horizontal direction (e.g., a direction extending parallel or substantially parallel to the upper surface 150s of the first RDL 150). A space (e.g., a void 432) may be formed (e.g., defined) between the upper surface 400s of the first molding layer 400 having the recess 435 and a lower surface 500s of the planarization layer 500. Accordingly, the upper surface 400s of the first molding layer 400 and the lower surface 500s of the planarization layer 500 may collectively at least partially define a void 432 between the upper surface 400s and the lower surface 500s. For example, as shown, at least the exposed one or more inner surfaces 420s (that at least partially define the upper surface 400s) and the lower surface 500s of the planarization layer 500 may collectively at least partially define the void 432 between the upper surface 400s and the lower surface 500s.

In some example embodiments, the planarization layer 500 may have a thickness (e.g., a thickness in the vertical direction) of about 100 nm to about 100 μm.

The conductive post structure 210 may extend through both of the first molding layer 400 and the planarization layer 500 in the vertical direction, and may contact portions of both of the first redistribution wiring structure 155 and the second redistribution wiring structure 655 to be electrically connected to both of the first redistribution wiring structure 155 and the second redistribution wiring structure 655.

In some example embodiments, the conductive post structure 210 may include a first conductive post 200 extending through the first molding layer 400 and a second conductive post 205 extending through the planarization layer 500.

In some example embodiments, the second conductive post 205 may have the same size or substantially the same size as the first conductive post 200, and respective sidewalls 200s and 205s of the first and second conductive posts 200 and 205 may be aligned with each other in the vertical direction. For example, the second conductive post 205 may have a planar area (e.g., a planar area in the horizontal direction, a cross-sectional area in the horizontal direction) that is the same or substantially the same in both size and shape as the planar area of the first conductive post 200, and/or proximate ends of the respective sidewalls 200s and 205s in the vertical direction may be aligned with each other in the vertical direction, such that respective sidewalls 200s and 205s of the first and second conductive posts 200 and 205 may be aligned with each other in the vertical direction to collectively define one or more sidewalls 210s extending continuously in the vertical direction between the first and second conductive posts 200 and 205, without discontinuous change in position of the one or more sidewalls 210s in the horizontal direction as the one or more sidewalls 210s extend in the vertical direction. In some example embodiments, the second conductive post 205 may have a planar area (e.g., a planar area in the horizontal direction, a cross-sectional area in the horizontal direction) greater or smaller than that of the first conductive post 200, and thus the respective sidewalls 200s and 205s of the first and second conductive posts 200 and 205 may not be aligned with each other, for example such that proximate ends of the respective sidewalls 200s and 205s in the vertical direction may be at least partially offset from each other in the horizontal direction.

In some example embodiments, the first and second conductive posts 200 and 205 may include the same material or substantially the same material so as not to be distinguished from each other. In some example embodiments, the first and second conductive posts 200 and 205 may include different materials from each other, or may be distinguished from each other even though the first and second conductive posts 200 and 205 include the same material.

In some example embodiments, the semiconductor package may include a plurality of conductive post structures 210 that may be spaced apart from each other in the horizontal direction, and may be arranged to surround the first semiconductor chip 300 in a plan view (e.g., a view directed in the vertical direction).

Each of the first and second conductive posts 200 and 205 may include a metal, e.g., copper, aluminum, etc.

The second RDL 650 may include insulation layers stacked in the vertical direction and a second redistribution wiring structure 655 in the insulation layers, and the second redistribution wiring structure 655 may include, e.g., redistribution wirings, vias, contact plugs, conductive pads, etc.

FIG. 1 shows that the second RDL 650 includes fourth, fifth, and sixth insulation layers 610, 620, and 630 sequentially stacked in the vertical direction, and the second redistribution wiring structure 655 is formed in the fourth, fifth and sixth insulation layers 610, 620 and 630. However, the inventive concepts are not limited thereto, and the second RDL 650 may include less than or more than three insulation layers sequentially stacked in the vertical direction. In some example embodiments, the second RDL 650 may omit one or more of the fourth, fifth or sixth insulation layers 610, 620, or 630.

Each of the redistribution wirings, vias, contact plugs, conductive pads, etc., included in the second redistribution wiring structure 655 may have various types of layouts in the insulation layers.

Each of the fourth to sixth insulation layers 610, 620 and 630 may include an organic material, e.g., photo imageable dielectric (PID). The redistribution wirings, vias, contact plugs, conductive pads, etc., included in the second redistribution wiring structure 655 may include a conductive material, e.g., a metal, a metal nitride, a metal silicide, etc.

In some example embodiments, the second RDL 650 may be disposed on the planarization layer 500 having the flat (e.g., planar or substantially planar and extending in the horizontal direction) upper surface 500u, and thus, as illustrated below with reference to FIGS. 2 to 8, a likelihood of an electrical short between elements of the second redistribution wiring structure 655 in the second RDL 650 may be reduced, minimized, or prevented. As a result, the reliability of the semiconductor package may be improved.

FIGS. 2, 3, 4, 5, 6, 7, and 8 are cross-sectional views illustrating a method of manufacturing a semiconductor package in accordance with some example embodiments.

Referring to FIG. 2, a first temporary adhesion layer 920 may be attached to a first carrier substrate 910, and a first RDL 150 may be formed on the first temporary adhesion layer 920.

The first carrier substrate 910 may include, e.g., a non-metallic or metallic plate, a silicon substrate, a glass substrate, etc. The first temporary adhesion layer 920 may include a material having adhesion by irradiating light or heating, or a release tape.

In some example embodiments, the first RDL 150 may include insulation layers sequentially stacked in the vertical direction and a first redistribution wiring structure 155 therein, and the first redistribution wiring structure 155 may include, e.g., redistribution wirings, via, contact plugs, conductive pads, etc.

FIG. 1 shows that the first RDL 150 includes first to third insulation layers 110, 120 and 130 sequentially stacked in the vertical direction, and the first redistribution wiring structure 155 is formed in the first to third insulation layers 110, 120 and 130.

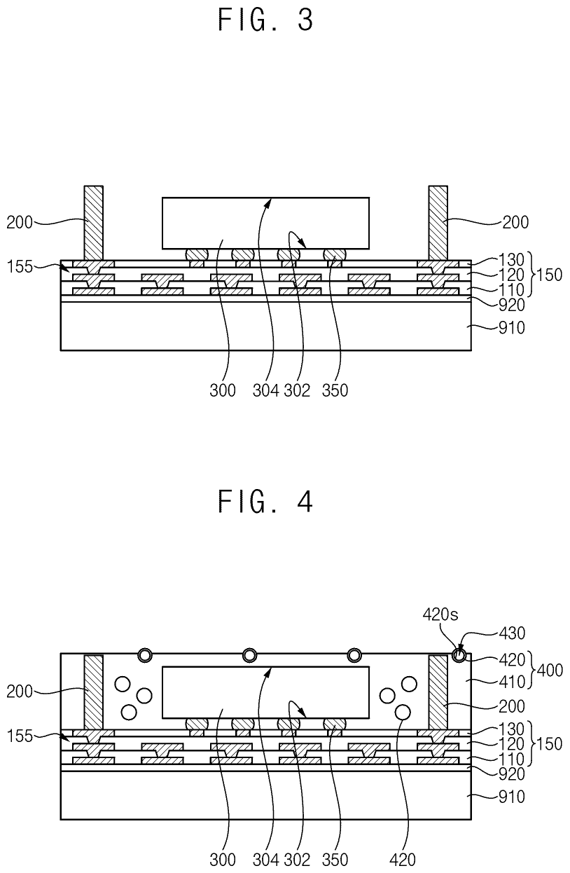

Referring to FIG. 3, a first conductive post 200 may be formed to contact a portion of the first redistribution wiring structure 155, and a first semiconductor chip 300 may be mounted to be electrically connected to a portion of the first redistribution wiring structure 155.

In some example embodiments, the first conductive post 200 may be formed by forming a first photoresist layer on the first RDL 150, forming a first opening to expose the portion of the first redistribution wiring structure 155, and performing, e.g., an electroplating process so as to form the first conductive post 200 on the exposed portion of the first redistribution wiring structure 155 in the first opening.

The first photoresist layer may be removed by, e.g., an ashing process and/or a stripping process, such that the first conductive post 200 remains on the first RDL 150 as shown in at least FIG. 3.

The first semiconductor chip 300 may be mounted (e.g., mounted on the first RDL 150) to be electrically connected to the portion of the first redistribution wiring structure 155 through the second conductive connection member 350. The second conductive connection member 350 may include, e.g., a conductive bump or a conductive ball.

The first semiconductor chip 300 may include first and second surfaces 302 and 304 opposite to each other in the vertical direction, and the first surface 302 of the first semiconductor chip 300 may face downwardly in the vertical direction when the first semiconductor chip 300 is mounted (e.g., mounted on the first RDL 150).

In some example embodiments, a plurality of first conductive posts 200 may be spaced apart from each other in the horizontal direction, and may surround the first semiconductor chip 300 in a plan view.

Referring to FIG. 4, a first molding layer 400 may be formed on the first RDL 150.

The first molding layer 400 may cover the first semiconductor chip 300, the second conductive connection member 350 and the first conductive post 200. The first molding layer 400 may directly contact the first RDL 150. The first molding layer 400 may directly contact the second conductive connection member 350. The first molding layer 400 may directly contact the first semiconductor chip 300. The first molding layer 400 may directly contact the first conductive post 200.

The first molding layer 400 may include, e.g., epoxy molding compound (EMC), which may include, e.g., a molding member 410 and a filler 420. As shown, the filler 420 may be partially or entirely in the molding member 410 (e.g., partially or entirely surrounded in both of horizontal planes and vertical planes by the molding member 410).

The filler 420 may include silica (SiO₂) and/or alumina (Al₂O₃), and may have a hardness higher than that of the molding member 410 and a coefficient of thermal expansion (CTE) lower than that of the molding member 410. The filler 420 may have a spherical shape or a shell shape including a void 430 therein. For example, the filler 420 may have a spherical shape or a shell shape having one or more inner surfaces 420s at least partially defining a void 430 within an interior of the filler 420. The filler 420 may be formed at an upper portion of the molding member 410 as well as at an inside thereof.

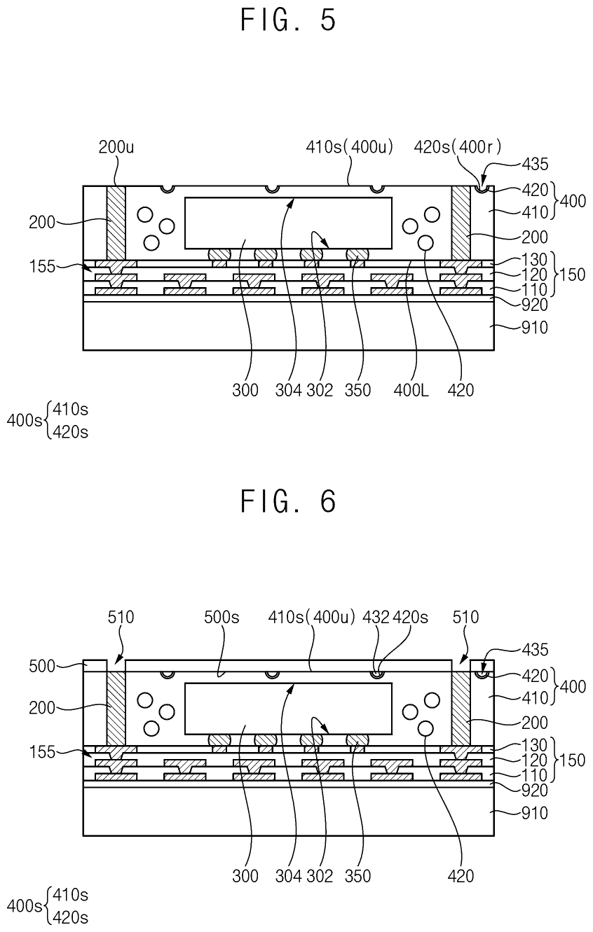

Referring to FIG. 5, for example, a grinding process may be performed on the upper portion of the first molding layer 400 to reduce a thickness (e.g., a thickness in the vertical direction) of the first molding layer 400, and an upper surface 200u of the first conductive post 200 may be exposed by the grinding process. As shown, an uppermost surface 410s in the vertical direction of the molding member 410, based on the grinding being performed on the upper portion of the first molding layer 400, may at least partially define an uppermost surface portion 400u of the first molding layer 400 and thus may at least partially define an upper surface 400s of the first molding layer 400. The uppermost surface 410s, and thus the uppermost surface portion 400u may be planar or substantially planar and extending in the horizontal direction. As described herein, an upper surface or an uppermost surface of a layer, structure, or the like may be a surface of the layer that is distal or furthest, in the vertical direction, among the surfaces of the layer, structure, or the like, from a lower surface 150L of the first RDL 150. As described herein, a lower surface or a lowermost surface of a layer, structure, or the like may be a surface of the layer that is proximate or closest, in the vertical direction, among the surfaces of the layer, structure, or the like, to the lower surface 150L of the first RDL 150. As shown, the lower surface 150L may be the lower surface of the first insulation layer 110, but example embodiments are not limited thereto.

In some example embodiments, when the grinding process is performed, an upper portion of one of the fillers 420 having a shell shape at the upper portion of the first molding layer 400 may be removed to expose the void 430 in the one of the fillers 420, which may be referred to as a recess 435, hereinafter. For example, the first molding layer 400 may have one or more surfaces, including for example one or more inner surfaces 420s of a shell shaped filler 420 that is exposed at the upper surface 400s of the first molding layer 400, that at least partially define a recess 435 into the first molding layer 400 (e.g., into an interior of the first molding layer 400, towards a lower surface 400L of the first molding layer 400, etc.) in the vertical direction from the uppermost surface portion 400u (e.g., uppermost surface 410s) of the first molding layer 400, where the upper surface 400s may be at least partially defined by the uppermost surface 410s of the molding member 410 (which may be planar or substantially planar) and the exposed one or more inner surfaces 420s of one or more fillers 420. For example, the first molding layer 400 may have one or more surfaces, including for example one or more inner surfaces 420s, which at least partially define a recess 435 at the upper surface 400s of the first molding layer 400. Such one or more inner surfaces 420s may be referred to as defining one or more recessed surface portions 400r of the upper surface 400s of the first molding layer 400. Thus, the first molding layer 400 may not be flat. For example, the upper surface 400s of the first molding layer 400 may not be planar, based on the upper surface 400s being collectively defined by at least the uppermost surface 410s of the molding member 410 (which defines an uppermost surface portion 400u that is planar or substantially planar and extending in the horizontal direction) and the one or more exposed inner surfaces 420s of one or more fillers 420 that may define one or more recessed surface portions 400r and may at least partially define one or more recesses 435 into the first molding layer 400 (e.g., into an interior of the first molding layer 400, towards a lower surface 400L of the first molding layer 400, etc.) from the uppermost surface 410s (e.g., from the uppermost surface portion 400u).

Referring to FIG. 6, a planarization layer 500 may be formed on the first molding layer 400 and the first conductive post 200, and may be partially removed to form a second opening 510 exposing an upper surface of the first conductive post 200.

In some example embodiments, the planarization layer 500 may include an element of a lamination tape, e.g., PSA, which may include, e.g., acryl, imide, silicon, etc. In some example embodiments, no recess may be formed on an upper surface of the planarization layer 500, which may be different from the first molding layer 400 having the recess 435 thereon (e.g., the recess at the upper surface 400s of the first molding layer 400), and thus the planarization layer 500 may have a flat upper surface 500u. For example, the planarization layer 500 may have an upper surface 500u that is planar or substantially planar. The upper surface 500u may extend in the horizontal direction.

The planarization layer 500 may at least partially fill the recess 435 at the upper surface 400s of the first molding layer 400, and may not entirely fill the recess 435. Thus, a void 432 may remain between the first molding layer 400 and the planarization layer 500. For example, as shown, at least a portion of the upper surface 400s of the first molding layer 400 and a lower surface 500s of the planarization layer 500 may collectively at least partially define a void 432 between the upper surface 400s of the first molding layer 400 and the lower surface 500s of the planarization layer 500. For example, as shown, at least the exposed one or more inner surfaces 420s (that at least partially define the upper surface 400s) and the lower surface 500s of the planarization layer 500 may collectively at least partially define the void 432 between the upper surface 400s and the lower surface 500s.

In some example embodiments, the second opening 510 may be formed by performing a laser drill on the planarization layer 500.

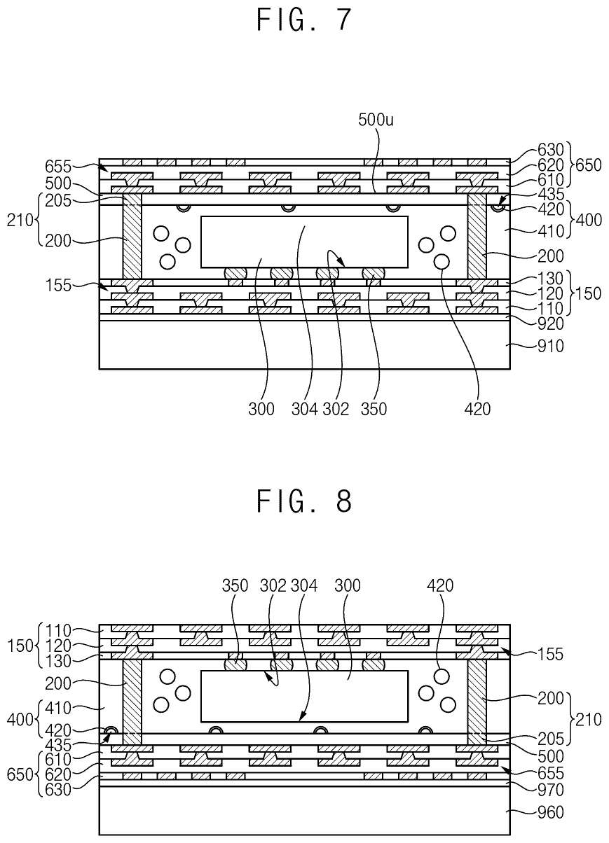

Referring to FIG. 7, for example, an electroplating process may be performed to form a second conductive post 205 in the second opening 510, and the first and second conductive posts 200 and 205 stacked in the vertical direction may collectively form (e.g., collectively define) a conductive post structure 210.

A second RDL 650 may be formed on the planarization layer 500 and the conductive post structure 210.

In some example embodiments, the second RDL 650 may include insulation layers stacked in the vertical direction and a second redistribution wiring structure 655 in the insulation layers, and the second redistribution wiring structure 655 may include, e.g., redistribution wirings, vias, contact plugs, conductive pads, etc. A portion of the second redistribution wiring structure 655 may contact the upper surface of the conductive post structure 210 (which may be defined by an upper surface of the second conductive post 205).

FIG. 7 shows that the second RDL 650 includes fourth, fifth and sixth insulation layers 610, 620 and 630 sequentially stacked in the vertical direction, and the second redistribution wiring structure 655 is formed in the fourth, fifth and sixth insulation layers 610, 620 and 630.

The second RDL 650 may be formed on the planarization layer 500 having a flat upper surface, and thus a likelihood of an electrical short between elements of the second redistribution wiring structure 655 in the second RDL 650 may be reduced, minimized, or prevented.

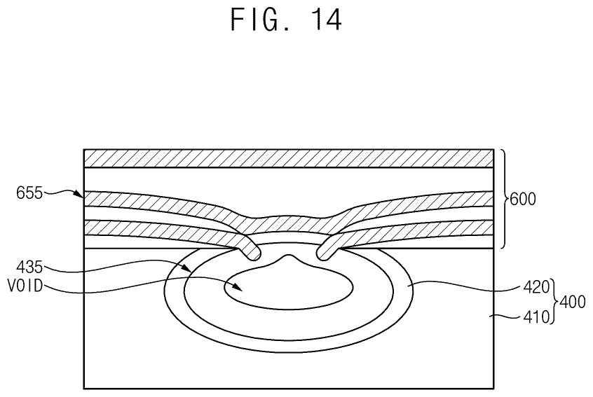

FIG. 14 is a drawing illustrating an electrical short generated in a second redistribution wiring structure of a semiconductor package in accordance with a comparative embodiment.

Referring to FIG. 7 together with FIG. 14, if the planarization layer 500 is not formed on the first molding layer 400 having the recess 435 thereon and the second RDL 650 is formed directly on the first molding layer 400, some of the wirings, vias, contact plugs, conductive pads, etc., of the second redistribution wiring structure 655 in the second RDL 650 may be formed in the recess 435 to contact each other, which may cause an electrical short therebetween.

However, in some example embodiments, the planarization layer 500 may be formed on the first molding layer 400 having the recess 435 thereon and may reduce, minimize, or prevent the likelihood of portions of the second RDL 650, including wirings, vias, contact plugs, conductive pads, etc., of the second redistribution wiring structure 655, from being formed in and/or from extending into the recess 435 to contact each other. For example, the portions of the second RDL 650, including wirings, vias, contact plugs, conductive pads, etc., of the second redistribution wiring structure 655 may be isolated from recesses 435 at the upper surface 400s of the first molding layer 400 and may be prevented from being formed in recesses based on the second RDL being formed on (e.g., directly on) the flat upper surface 500u of the planarization layer 500 which may not include any or substantially any recesses due to being a flat (e.g., planar or substantially planar) upper surface 500 extending in the horizontal direction. As a result, based on including the planarization layer 500 contacting the upper surface 400s of the first molding layer 400, a semiconductor package may have improved reliability due to reduced, minimized, or prevented likelihood of electrical shorts between wirings, vias, contact plugs, conductive pads, etc., of the second redistribution wiring structure 655 due to reducing, minimizing, or preventing the likelihood of such wirings, vias, contact plugs, conductive pads, etc., of the second redistribution wiring structure 655 from being formed in a recess 435 at the upper surface 400s of the first molding layer 400.

Referring to FIG. 8, a second temporary adhesion layer 970 may be attached to an upper surface of the second RDL 650 and a second carrier substrate 960 (e.g., between the second RDL 650 and the second carrier substrate 960), and a structure including the second carrier substrate 960 may be flipped, and the first temporary adhesion layer 920 and the first carrier substrate 910 may be removed from the structure including the second carrier substrate 960.

The second carrier substrate 960 may include, e.g., a non-metallic or metallic plate, a silicon substrate, a glass substrate, etc. The second temporary adhesion layer 970 may include a material having adhesion by irradiating light or heating, or a release tape.

Referring to FIG. 1 again, a first conductive connection member 180 may be formed to contact a portion of the first redistribution wiring structure 155 in the first RDL 150, and the structure may be flipped to complete the manufacturing of the semiconductor package.

As illustrated above, the first molding layer 400, which may be disposed on the first RDL 150 and cover the first semiconductor chip 300, the first conductive post 200 and the second conductive connection member 350, may include the filler 420 in addition to the molding member 410 so as to increase the hardness of the first molding layer 400 and reduce the CTE, and during the griding process on the upper portion of the first molding layer 400, the void 430 included in the filler 420 may be exposed to form the recess 435 at the upper surface 400s of the first molding layer 400.

Thus, an electrical short may be generated between elements of the second redistribution wiring structure 655 in the second RDL 650 due to the unevenness of the upper surface 400s of the first molding layer 400 (e.g., based on the upper surface 400s including non-planar portions, which may include one or more recessed surface portions 400r defined by one or more exposed inner surfaces 420s that at least partially define one or more recesses 435). However, in some example embodiments, the planarization layer 500 having a flat upper surface 500u may be further formed on the first molding layer 400 and the second RDL 650 may be formed on the planarization layer 500, so that a likelihood of an electrical short between the elements of the second redistribution wiring structure 655 in the second RDL 650 may be reduced, minimized, or prevented. For example, the planarization layer 500 may interpose between the first molding layer 400 having the uneven, at least partially non-planar upper surface 400s and the second RDL 650, where the planarization layer 500 has a flat (e.g., planar or substantially planar and extending in the horizontal direction) upper surface 500u despite the planarization layer 500 being on (e.g., directly on, in contact with, contacting, etc.) the uneven (e.g., partially non-planar) upper surface 400s of the first molding layer 400. As a result, the likelihood that elements of the second redistribution wiring structure 655 may be at least partially formed in a recess of a surface upon which the second RDL 650 is formed may be reduced, minimized, or prevented, due to the second RDL 650 including the second redistribution wiring structure 655 being formed on (e.g., directly on, contacting, in contact with, etc.) the flat upper surface 500u of the planarization layer 500 despite the planarization layer 500 being in contact (e.g., at the lower surface 500s thereof) with an at least partially non-planar upper surface 400s of the first molding layer 400.

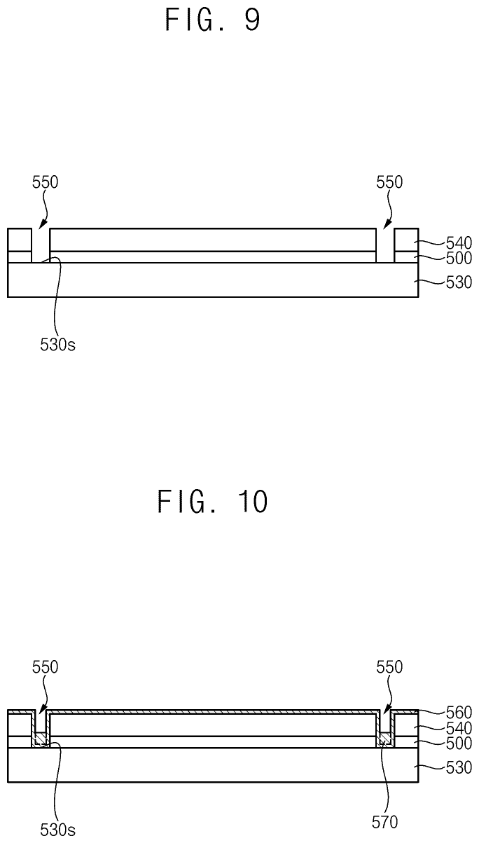

FIGS. 9, 10, and 11 are cross-sectional views illustrating a method of forming the second conductive post 205 in the planarization layer 500 in accordance with some example embodiments, which may correspond to example embodiments shown in FIGS. 6 and 7.

Referring to FIG. 9, a second photoresist layer 540 having (e.g., at least partially defining) a third opening 550 may be formed on a lamination tape including a support member 530 and a planarization layer 500 stacked in the vertical direction (e.g., a direction extending perpendicular to an upper surface 500u of the planarization layer 500), and the planarization layer 500 may be etched using the second photoresist layer 540 as an etching process mask so that the third opening 550 may be enlarged in the vertical direction to extend through the planarization layer 500 (e.g., through a thickness of the planarization layer as shown) to expose an upper surface 530s of the support member 530.

The support member 530 may include polyethylene terephthalate (PET), polyethylene naphthalate (PEN), polyethylene oxide (PO), aramid, polyetheretherketones (PEEK), polystyrene sulfonate (PSS), etc., and the planarization layer 500 may include, e.g., PSA.

Referring to FIG. 10, a seed layer 560 may be formed on a sidewall of the third opening 550, an upper surface 530s of the support member 530 exposed by the third opening 550 and an upper surface of the second photoresist layer 540, and for example, an electroplating process may be performed to form a conductive layer 570 at a lower portion of the third opening 550 (e.g., a portion of the third opening 550 that is proximate to the upper surface 530s of the support member 530).

Each of the seed layer 560 and the conductive layer 570 may include, e.g., copper, aluminum, etc., and if the seed layer 560 and the conductive layer 570 include the same material or substantially the same material, the seed layer 560 and the conductive layer 570 may be merged with each other.

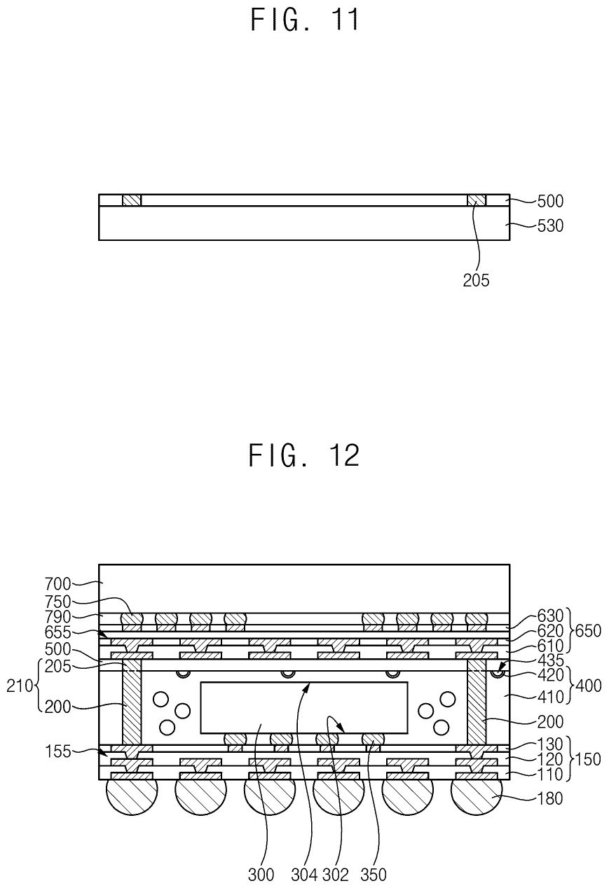

Referring to FIG. 11, a planarization process may be performed on the seed layer 560, the second photoresist layer 540 and an upper portion of the conductive layer 570 until an upper surface of the planarization layer 500 is exposed to form a second conductive post 205 extending through the planarization layer 500.

The planarization process may include, e.g., a grinding process, a chemical mechanical polishing (CMP) process.

The planarization layer 500 including the second conductive post 205 may be bonded onto the first molding layer 400 and the first conductive post 200, and the support member 530 may be removed so that the first and second conductive posts 200 and 205 stacked in the vertical direction may collectively form a conductive post structure 210.

A second RDL 650 may be formed on the planarization layer 500 and the conductive post structure 210, for example to provide a semiconductor package as shown in FIG. 7.

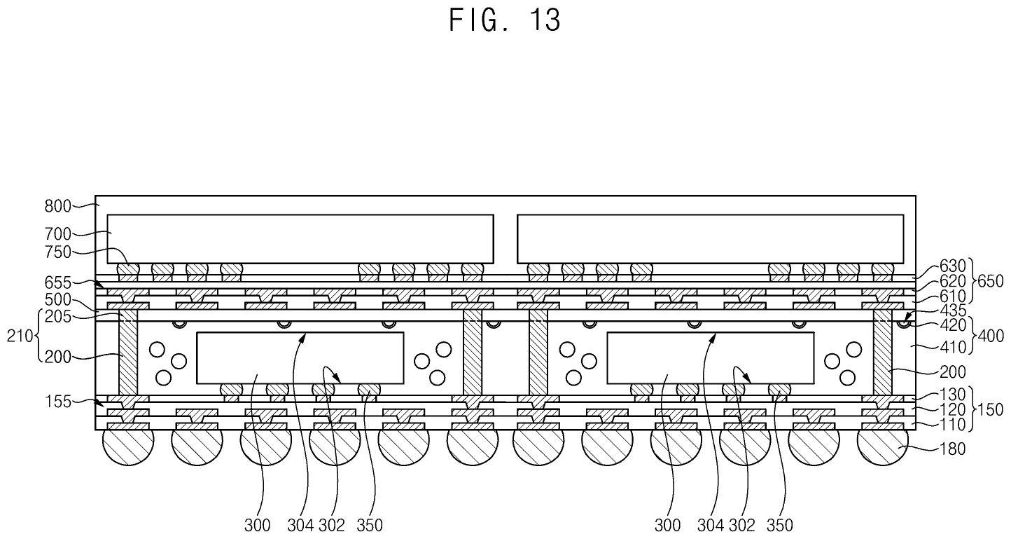

FIGS. 12 and 13 are cross-sectional views illustrating semiconductor packages in accordance with some example embodiments.

These semiconductor packages may be manufactured by stacking additional semiconductor chips on the semiconductor package of FIG. 1, and repeated explanations are omitted herein.

Referring to FIG. 12, a second semiconductor chip 700 may be mounted on the second RDL 650 with a third conductive connection member 750 between the second semiconductor chip 700 and the second RDL 650, and a second molding layer 790 may be interposed between (e.g., directly between or indirectly between) the second RDL 650 and the second molding layer 790 to cover the third conductive connection member 750.

In some example embodiments, the second semiconductor chip 700 may be a memory chip including a memory device. In some example embodiments, the first semiconductor chip 300 may be a logic chip including a logic device.

The third conductive connection member 750 may be, e.g., a conductive bump or a conductive ball. The third conductive connection member 750 may include solder that is an alloy or a metal, for example an alloy of tin, silver, copper, aluminum, nickel, etc., or a metal including copper, aluminum, nickel, tin, silver, etc.

The second molding layer 790 may include, e.g., EMC. In some example embodiments, an underfill member or an adhesive layer including non-conductive film (NCF) may be formed between (e.g., directly between or indirectly between) the second RDL 650 and the second semiconductor chip 700.

Referring to FIG. 13, a semiconductor package may include a plurality (e.g., two) first semiconductor chips 300 on the first RDL 150, where the plurality of first semiconductor chips 300 may be spaced apart from each other in the horizontal direction, and a plurality (e.g., two) second semiconductor chips 700 on the second RDL 650, where the plurality of second semiconductor chips 700 may be spaced apart from each other in the horizontal direction.

In some example embodiments, each semiconductor chip of the plurality of first semiconductor chips 300 and the plurality of second semiconductor chips 700 may be a memory chip including a memory device. In some example embodiments, each first semiconductor chip 300 of the plurality of first semiconductor chips 300 may be a logic chip including a logic device, and each second semiconductor chip 700 of the plurality of second semiconductor chips 700 may be a memory chip including a memory device.

FIG. 13 shows a semiconductor package including two first semiconductor chips 300 spaced apart from each other in the horizontal direction and two second semiconductor chips 700 spaced apart from each other in the horizontal direction. However, the inventive concepts are not limited thereto, and in some example embodiments a semiconductor package may include more than two first semiconductor chips 300 and more than two second semiconductor chips 700 that may be mounted on the first and second RDLs 150 and 650, respectively.

A third molding layer 800 may be formed on (e.g., directly on or indirectly on the second RDL 650, and the third molding layer 800 may cover the second semiconductor chips 700 and the third conductive connection member 750. The third molding layer 800 may include, e.g., EMC. The third molding layer 800 may directly contact each of the second semiconductor chips 700. The third molding layer 800 may directly contact some or all of the third conductive connection members 750.

The foregoing is illustrative of some example embodiments and is not to be construed as limiting thereof. Although some example embodiments have been described, those skilled in the art will readily appreciate that many modifications are possible in some example embodiments without materially departing from the novel teachings and advantages of the present inventive concepts. Accordingly, all such modifications are intended to be included within the scope of example embodiments as defined in the claims.

What is claimed is:

1. A semiconductor package, comprising:
a first redistribution layer (RDL), the first RDL including a first redistribution wiring structure;
a first semiconductor chip on the first RDL, the first semiconductor chip electrically connected to the first redistribution wiring structure;
a molding layer on the first RDL, the molding layer covering the first semiconductor chip, the molding layer having one or more surfaces at least partially defining a recess at an upper surface of the molding layer;
a planarization layer contacting the upper surface of the molding layer, the planarization layer having a flat upper surface; and
a second redistribution layer (RDL) on the planarization layer, the second RDL including a second redistribution wiring structure,
wherein the upper surface of the molding layer and a lower surface of the planarization layer collectively at least partially define a void between the upper surface of the molding layer and the lower surface of the planarization layer.

2. The semiconductor package according to claim 1, wherein the planarization layer includes pressure sensitive adhesive (PSA).

3. The semiconductor package according to claim 1, wherein the molding layer includes
a molding member, and
a filler in the molding member.

4. The semiconductor package according to claim 3, wherein
the molding member includes epoxy, and
the filler includes silica (SiO₂), alumina (Al₂O₃), boron nitride (BN), aluminum nitride (AlN), or diamond.

5. The semiconductor package according to claim 3, wherein
the filler is at an inside of the molding member and has a spherical shape, or
the filler is at an upper portion of the molding member and has a shell shape surrounding the recess.

6. The semiconductor package according to claim 1, further comprising:
a conductive post structure extending through both of the molding layer and the planarization layer in a vertical direction, the vertical direction perpendicular to an upper surface of the first RDL, the conductive post structure contacting both of the first redistribution wiring structure and the second redistribution wiring structure to be electrically connected to both of the first redistribution wiring structure and the second redistribution wiring structure.

7. The semiconductor package according to claim 6, wherein the conductive post structure includes
a first conductive post extending through the molding layer, and
a second conductive post extending through the planarization layer.

8. The semiconductor package according to claim 7, wherein respective sidewalls of the first and second conductive posts are aligned with each other in the vertical direction.

9. The semiconductor package according to claim 8, further comprising:
a second semiconductor chip on the second RDL, the second semiconductor chip electrically connected to the second redistribution wiring structure.

10. The semiconductor package according to claim 9, wherein
the first semiconductor chip includes a logic device, and
the second semiconductor chip includes a memory device.

11. A semiconductor package, comprising:
a first redistribution layer (RDL), the first RDL including a first redistribution wiring structure;
a first semiconductor chip on the first RDL, the first semiconductor chip electrically connected to the first redistribution wiring structure;
a molding layer on the first RDL, the molding layer covering the first semiconductor chip, the molding layer including
a molding member, and
a filler in the molding member, the filler having a shell shape having one or more inner surfaces at least partially defining a recess into an interior of the molding layer in a vertical direction from an uppermost surface of the molding member, the vertical direction perpendicular to an upper surface of the first RDL;
a planarization layer contacting an upper surface of the molding layer, the planarization layer having a flat upper surface, the planarization layer including a pressure sensitive adhesive (PSA); and
a second redistribution layer (RDL) on the planarization layer, the second RDL including a second redistribution wiring structure.

12. The semiconductor package according to claim 11, wherein
the molding member includes epoxy, and
the filler includes silica (SiO₂), alumina (Al₂O₃), boron nitride (BN), aluminum nitride (AlN), or diamond.

13. The semiconductor package according to claim 11, further comprising:
a conductive post structure extending through the molding layer and the planarization layer in the vertical direction, the conductive post structure contacting both of the first redistribution wiring structure and the second redistribution wiring structure to be electrically connected to both of the first redistribution wiring structure and the second redistribution wiring structure.

14. The semiconductor package according to claim 13, wherein the conductive post structure includes
a first conductive post extending through the molding layer, and
a second conductive post extending through the planarization layer.

15. The semiconductor package according to claim 14, wherein respective sidewalls of the first and second conductive posts are aligned with each other in the vertical direction.

16. The semiconductor package according to claim 11, further comprising:
a second semiconductor chip on the second RDL, the second semiconductor chip electrically connected to the second redistribution wiring structure.

17. A semiconductor package, comprising:
a first redistribution layer (RDL), the first RDL including a first redistribution wiring structure;
a first conductive connection member on a lower surface of the first RDL, the first conductive connection member contacting the first redistribution wiring structure;
a second conductive connection member on the first RDL, the second conductive connection member contacting the first redistribution wiring structure;
a first semiconductor chip contacting an upper surface of the second conductive connection member;
a molding layer on the first RDL, the molding layer covering both of the first semiconductor chip and the second conductive connection member, the molding layer having one or more surfaces at least partially defining a recess at an upper surface of the molding layer;
a planarization layer contacting the upper surface of the molding layer, the planarization layer having a flat upper surface;
a second redistribution layer (RDL) contacting an upper surface of the planarization layer, the second RDL including a second redistribution wiring structure;
a conductive post structure extending through both of the molding layer and the planarization layer, the conductive post structure contacting both of the first redistribution wiring structure and the second redistribution wiring structure;
a third conductive connection member on the second RDL, the third conductive connection member contacting the second redistribution wiring structure; and
a second semiconductor chip contacting an upper surface of the third conductive connection member,
wherein the upper surface of the molding layer and a lower surface of the planarization layer collectively at least partially define a void between the upper surface of the molding layer and the lower surface of the planarization layer.

18. The semiconductor package according to claim 17, wherein
the first semiconductor chip includes a logic device, and
the second semiconductor chip includes a memory device.

19. The semiconductor package according to claim 17, further comprising:
a plurality of first semiconductor chips spaced apart from each other in a horizontal direction, the horizontal direction parallel to an upper surface of the first RDL, the plurality of first semiconductor chips including the first semiconductor chip, and
a plurality of second semiconductor chips spaced apart from each other in the horizontal direction, the plurality of second semiconductor chips including the second semiconductor chip.

20. The semiconductor package according to claim 19, wherein each semiconductor chip of the plurality of first semiconductor chips and the plurality of second semiconductor chips includes a memory device.
